(19) United States
(12) Patent Application Publication
(10) Pub. No.: US 2013/0162892 A1
(43) Pub. Date: Jun. 27, 2013

(54) COG PACKAGE AND CAMERA MODULE HAVING THE SAME

(71) Applicant: Samsung Electro-Mechanics CO., LTD., Suwon (KR)

(72) Inventor: Joon Hyuk HAN, Suwon (KR)

(73) Assignee: Samsung Electro-Mechanics CO., LTD., Suwon (KR)

(21) Appl. No.: 13/707,800

(22) Filed: Dec. 7, 2012

(30) Foreign Application Priority Data
Dec. 21, 2011 (KR) 10-2011-0138826

(51) Int. Cl. H01L 31/02

(52) U.S. Cl. CPC H01L 31/02
USPC 348/360; 257/435

(57) ABSTRACT

There is provided a COG package. The COG package includes: a transparent circuit board formed of a light transmitting material; an imaging device fixedly disposed on the transparent circuit board; a solder part formed on the transparent circuit board so as to be disposed outwardly of the imaging device; and a light shielding member mounted on a bottom surface of the imaging device to prevent light from being incident on the bottom surface of the imaging device and being transmitted through the imaging device.

### CROSS-REFERENCE TO RELATED APPLICATIONS

This application claims the priority of Korean Patent Application No. 10-2011-0138826 filed on Dec. 21, 2011, in the Korean Intellectual Property Office, the disclosure of which is incorporated herein by reference.

### BACKGROUND OF THE INVENTION

1. Field of the Invention

The present invention relates to a chip-on-glass (COG) package and a camera module having the same.

2. Description of the Related Art

Recently, various technologies for mobile devices allowing for portability as well as enhanced voice information and data transmitting and receiving capabilities have been developed and rapidly disseminated. In particular, a camera module-mounted terminal provided by allowing a digital camera technology-based camera module to be merged with a portable wireless communications terminal to include a camera function for capturing and storing moving and still images of a subject or object and transmitting the moving and still images to the subject thereof or a third party has been used.

In addition, as the information communications technology and the display device industries have rapidly developed in recent times, demand for inexpensive, multi-functional electronic components used therefore having low levels of power consumption has continuously increased.

Further, efforts to implement thin, small, light (compact) electronic devices using the electronic components have also been repeatedly undertaken. These efforts have been realized by using semiconductor devices as core components.

Recently, the use of a chip-on-glass (COG) package has been increased.

However, in the case of the COG package, light incident on a bottom surface of an imaging device may be transmitted through the imaging device and reach an image forming region to form unnecessary images.

That is, the quality of the image of the bottom surface of the imaging device may be deteriorated due to light incident through the bottom surface thereof.

In the following Related Art Document, Patent Document 1 discloses a micro fine pitch COG technology having an anisotropic conductive film, while Patent Document 2 discloses a semiconductor imaging device using flip chip bumping.

### RELATED ART DOCUMENT

### (Patent Document 1) Korean Patent Laid-Open Publication No. 2003-0004741

### (Patent Document 2) Korean Patent Laid-Open Publication No. 2003-0069321

### SUMMARY OF THE INVENTION

An aspect of the present invention provides a COG package and a camera module having the same, capable of suppressing light from being transmitted through a bottom surface of an imaging device and being transmitted therethrough.

According to an aspect of the present invention, there is provided a chip on glass (COG) package, including: a transparent circuit board formed of a light transmitting material; an imaging device fixedly disposed on the transparent circuit board; a solder part formed on the transparent circuit board so as to be disposed outwardly of the imaging device; and a light shielding member mounted on a bottom surface of the imaging device to prevent light from being incident on the bottom surface of the imaging device and being transmitted through the imaging device.

The light shielding member may be formed of an opaque metal thin film or light shielding tape.

The solder part may be provided in plural to be spacedly disposed at edges of the transparent circuit board.

According to another aspect of the present invention, there is provided a camera module, including: a lens assembly including at least one lens; a COG package receiving light incident through the lens assembly and including a light shielding member preventing light from being incident through a bottom surface of an imaging device; and a housing having the lens assembly and the COG package spacedly accommodated therein.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating a camera module having a COG package according to an embodiment of the present invention;

FIG. 2 is a bottom perspective view illustrating the COG package according to the embodiment of the present invention; and

FIG. 3 is a side view illustrating the COG package according to the embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

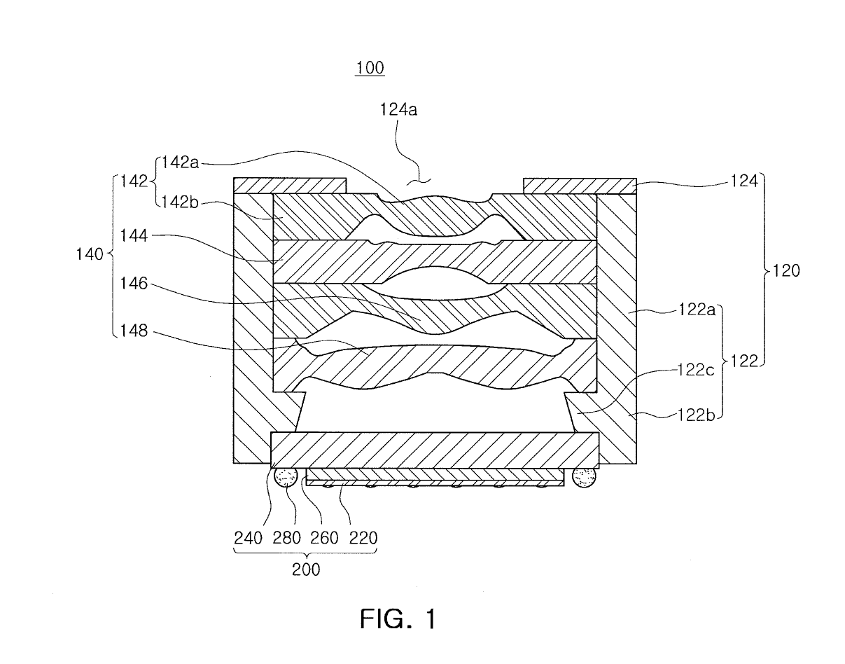

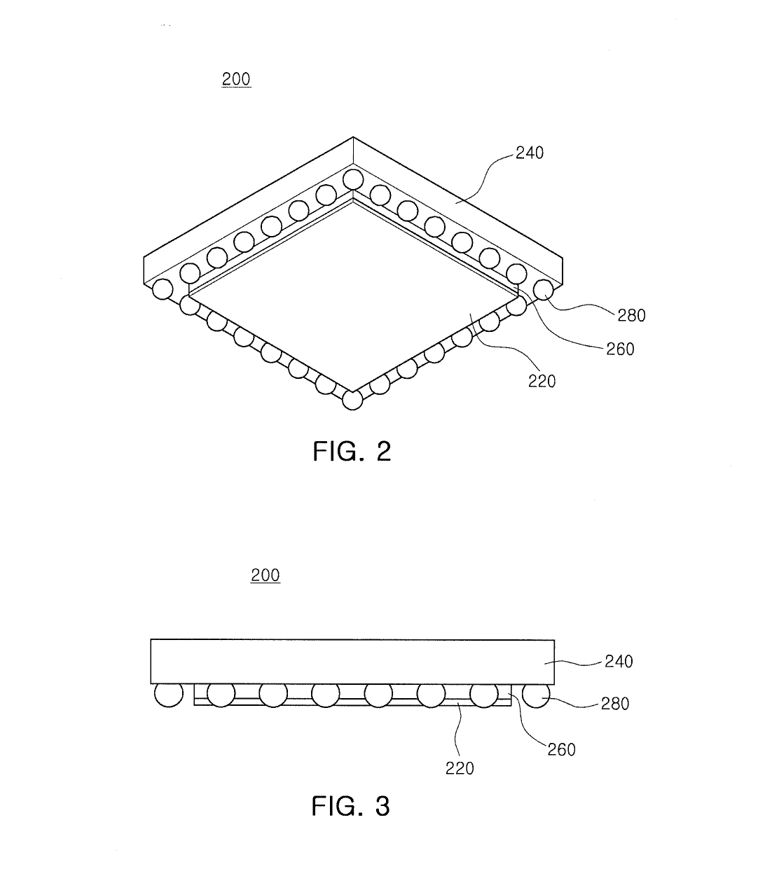

FIG. 1 is a schematic cross-sectional view illustrating a camera module having a COG package according to an embodiment of the present invention, FIG. 2 is a bottom perspective view illustrating the COG package according to the embodiment of the present invention, and FIG. 3 is a side view illustrating the COG package according to the embodiment of the present invention.

Referring to FIGS. 1 through 3, a camera module 100 according to an embodiment of the present invention may include a housing 120, a lens assembly 140, and a chip-on-glass (COG) package 200.

The housing 120 has the lens assembly 140 and the COG package 200 spacedly accommodated therein. Further, the housing 120 may have an inner space and a structure in which the upper and lower portions of the housing 120 are opened.

Meanwhile, the housing 120 may be configured of a body 122 in which the lens assembly 140 and the COG package 200 are accommodated and a cover 124 coupled to an upper portion of the body 122.

Further, the body 122 may include a first side wall part 122a in which the lens assembly 140 is accommodated and a second side wall part 122b in which the COG package 200 is accommodated.

Further, the lens assembly 140 is accommodated in the inner space of the first side wall part 122a and may be directly inserted into the first side wall part 122a in the state in which a plurality of lenses are bonded to each other.

Meanwhile, the COG package 200 is accommodated in the inner space of the second side wall 122b and may be press-fitted to the second side wall part 122b or fixed to the second side wall part 122b by an adhesive.

Further, the second side wall part 122b includes four side walls and the thicknesses of two side walls, for example, a left side wall and a right side wall that face each other, based on an optical axis, may be formed differently so as to adjust the aligning of the lens assembly 140 and the COG package 200.

Further, the body 122 may be provided with a spacer 122c so that the lens assembly 140 and the COG package 200 are disposed so as to be spaced apart from each other by a predetermined interval. The spacer 122c may be protruded from an inner circumferential surface of the body 122. The spacer 122c may have a thickness according to a preset focal distance of the lens assembly 120.

The cover 124 may be formed of a conductive material so as to shield electromagnetic waves and is disposed to cover the upper portion of the body 122. In addition, a central portion of the cover 124 may be formed with an opening part 124a .

Meanwhile, the cover 124 may serve to shield unnecessary light incident on the lens assembly 120.

The lens assembly 140 may include a first lens 142, a second lens 144, a third 146, and a fourth lens 148 sequentially disposed from an object side. Meanwhile, the embodiment of the present invention describes, by way of example, the case in which the lens assembly 140 is configured of four lenses, but is not limited thereto. Accordingly, the lens assembly 140 may be configured of four or less lenses or four or more lenses.

In addition, the embodiment of the present invention describes, by way of example, the case in which the lens assembly 140 has the structure in which the plurality of lenses are bonded to each other, but is not limited thereto. Accordingly, the lens assembly 140 may have a structure in which the plurality of lenses are inserted into a lens barrel and assembled therein and the structure of the lens assembly 140 may be variously changed according to design conditions.

Further, the lens collects or effuses light incident from an object through a transparent material having a spherical surface or an aspherical surface, thereby focusing an optical image. As the lens, a plastic lens or a glass lens may be used.

Meanwhile, the plastic lens is manufactured on a wafer scale by putting a resin into a mold and pressing and curing it and is then individualized, such that the plastic lens may be inexpensively manufactured and mass produced.

Further, the glass lens may be implemented in terms of high resolution, but may be manufactured by cutting and grinding glass, such that the glass lens cannot be easily implemented as a lens other than as a spherical or a planar lens, due to a complicated process and a high cost.

Further, a center of the first lens 142 is provided with a lens functional part 142a formed to have a spherical surface or an aspherical surface, and a circumference of the lens functional part 142a is provided with a flange part 142b forming an outside of the lens functional part 142a.

Similarly, the second lens 144 to the fourth lens 148 also include the lens functional part and the flange part, which are not denoted by reference numerals in the drawings.

The lens functional parts mounted in the first lens 142 to the fourth lens 148 may have various shapes, such as a meniscus shape having a shape protruded or depressed toward an object side, a meniscus shape having a shape protruded or depressed upwardly, or a meniscus shape having a shape depressed upwardly from a central portion and then, a meniscus shape having a shape protruded upwardly toward the flange part, and the like.

Further, the flange part may also serve as a spacer that spaces the lens function parts of adjacent lens when adjacent lens are bonded to each other.

The COG package 200 may receive light incident through the lens assembly 140 and include a light shielding member 220 that shields light incident through the bottom surface of the imaging device.

Meanwhile, as illustrated in more detail in FIGS. 2 and 3, the COG package 200 may include a transparent circuit board 240, an imaging device 260, solder parts 280, and the light shielding member 220.

The transparent circuit board 240 may be formed of a light transmitting material. Further, the transparent circuit board 240 may be a glass board through which light may be transmitted or a board formed of a polyimide film.

Further, the transparent circuit board 240 may be provided with a conductor pattern (not illustrated) for electrically connecting the imaging device 260 with external devices.

Further, the transparent circuit board 240 may have a rectangular parallelepiped shape. However, the transparent circuit board is not limited thereto and therefore, the shape thereof may be variously changed.

The imaging device 260 may be fixedly mounted on the transparent circuit board 240. That is, the imaging device 260 is fixedly mounted on the bottom surface of the transparent circuit board 240 and may be connected with the conductor pattern.

The imaging device 260 is a device that receives light and converts the received light into an electric signal. Further, the imaging device 260 may be configured of a charged couple device (CCD) sensor chip or a complementary metal oxide semiconductor (CMOS) sensor chip.

Meanwhile, a CCD sensor chip, based on an analog circuit, is a scheme of spreading light incident on the lens to several cells to allow each cell to store charges for the light and determining a brightness degree due to a magnitude of the charges and then, transmitting the determined brightness degree to a converting device to represent color.

Therefore, the charge coupled device (CCD) sensor chip may implement clear image quality representation but has a large data storage requirement and high power consumption, and therefore, has been mainly used for a digital camera requiring high image quality.

Further, a complementary metal oxide semiconductor (CMOS) sensor chip is configured by integrating analog signal and digital signal processing circuits in a semiconductor. Compared with the CCD sensor chip, the CMOS sensor chip consumes about 1/10 of the power thereof, and may be manufactured as a smaller product since the entirety of necessary components are configured in a single chip. In addition to the description above, due to the recent development of a technology level, the CMOS sensor chip implements high image quality and has been used for in several types of device such as a digital camera, a camera phone, a personal media player (PMP), and the like.

However, the imaging device 260 is not limited to being configured of the above two sensor chips.

The solder parts 280 may be formed on the transparent circuit board 240 so as to be disposed outwardly of the imaging device 260. Further, the solder parts 280 may serve to be connected to terminals of a main board (not illustrated) in which the camera module 100 is mounted.

Further, the plurality of solder parts 280 may be formed of a conductive paste, in detail, a solder paste or silver epoxy (Ag-epoxy) resin.

Meanwhile, the plurality of solder parts 280 may be spacedly disposed at edges of the transparent circuit board 240. Further, the plurality of solder parts 280 are spacedly disposed at the edges of the transparent circuit board 240, such that light may be incident on the imaging device 260 through a space therebetween.

The light shielding member 220 is mounted on the bottom surface of the imaging device 260 to prevent light from being incident on the bottom of the imaging device 260 and being transmitted through the imaging device 260.

Meanwhile, the light shielding member 220 may be formed of an opaque metal thin film or light shielding tape. In addition, the light shielding member 220 may be mounted in the imaging device 260 in a wafer state when the imaging device 260 molded by cutting the wafer is manufactured.

In this case, the manufacturing process may be simplified and the manufacturing yield may be improved.

Further, the light shielding member 220 may serve to reinforce the strength of the imaging device 260 when the imaging device 260 is relatively thin by the backgrinding of the imaging device 260. Therefore, the light shielding member 220 may suppress the damage of the imaging device 260 even at the time of an external impact.

As described above, according to embodiments of the present invention, the light shielding member 220 may reduce the incidence of light through the bottom surface of the imaging device 260.

Therefore, the light shielding member 220 may suppress the formation of the image due to the light incident on the image forming region of the imaging device 260 through the bottom surface of the imaging device 260.

As a result, acquired image quality may be improved.

Meanwhile, the light shielding member 220 may reinforce the strength of the imaging device 260.

While the present invention has been shown and described in connection with the embodiments described previously, it will be apparent to those skilled in the art that modifications and variations can be made without departing from the spirit and scope of the invention as defined by the appended claims.

What is claimed is:

1. A chip on glass (COG) package, comprising:
a transparent circuit board formed of a light transmitting material;
an imaging device fixedly disposed on the transparent circuit board;
a solder part formed on the transparent circuit board so as to be disposed outwardly of the imaging device; and
a light shielding member mounted on a bottom surface of the imaging device to prevent light from being incident on the bottom surface of the imaging device and being transmitted through the imaging device.

2 . The COG package of claim 1, wherein the light shielding member is formed of an opaque metal thin film or light shielding tape.

3. The COG package of claim 1, wherein the solder part is provided in plural to be spacedly disposed at edges of the transparent circuit board.

4. A camera module, comprising:
a lens assembly including at least one lens;
a COG package receiving light incident through the lens assembly and including a light shielding member preventing light from being incident through a bottom surface of an imaging device; and
a housing having the lens assembly and the COG package spacedly accommodated therein.

5. The camera module of claim 4, wherein the COG package includes:
a transparent circuit board formed of a light transmitting material;
an imaging device fixedly disposed on the transparent circuit board;
a solder part formed on the transparent circuit board so as to be disposed outwardly of the imaging device; and
a light shielding member mounted on the bottom surface of the imaging device to prevent light from being incident on the bottom surface of the imaging device and being transmitted through the imaging device.

6. The camera module of claim 5, wherein the light shielding member is formed of an opaque metal thin film or light shielding tape.

7. The camera module of claim 5, wherein the solder part is provided in plural to be spacedly disposed at edges of the transparent circuit board.
